(19) United States
(12) Patent Application Publication
(10) Pub. No.: US 2012/0263989 A1
(43) Pub. Date: Oct. 18, 2012

(54) RACK HOUSING ASSEMBLY AND ENERGY STORAGE APPARATUS HAVING THE SAME

(75) Inventors: Jeong-Deok BYUN, Yongin-si (KR); Eun-Ok KWAK, Yongin-si (KR); Jong-Wook YOON, Yongin-si (KR); Byoung-Ju KIM, Yongin-si (KR)

(73) Assignee: Samsung SDI Co., Ltd., Yongin-si (KR)

(21) Appl. No.: 13/333,046

(22) Filed: Dec. 21, 2011

(30) Foreign Application Priority Data
Apr. 15, 2011 (KR) 10-2011-0035157

(51) Int. Cl. H01M 2/10; H05K 5/03; H05K 7/14; H05K 5/02

(52) U.S. Cl. 429/99; 429/100; 312/111; 361/752

(57) ABSTRACT

A rack housing assembly and an energy storage apparatus having the rack housing assembly are disclosed. The rack housing assembly may include a rack housing defining a plurality of accommodation spaces, each having open front side configured to house a battery tray. The rack housing assembly may also include an anchor member formed on at least at one side of the rack housing and be configured to fix the rack housing to a wall member of an installation space. The rack housing assembly intensively may house a plurality of battery trays and be configured to electrically connect the housed battery trays so that the housed battery trays are modulated. The rack housing assembly may include an improved anti-vibration characteristic with respect to external shocks or vibrations that may be generated during transfer.

### CROSS-REFERENCE TO RELATED APPLICATIONS

This application claims priority to and the benefit of Korean Patent Application No. 10-2011-0035157, filed on Apr. 15, 2011, in the Korean Intellectual Property Office, the disclosure of which is incorporated herein by reference in its entirety.

### BACKGROUND

1. Field of the Disclosure

One or more embodiments of the present disclosure relate to a rack housing assembly and an energy storage apparatus having the rack housing assembly.

2. Description of the Related Art

As environmental destruction, exhaustion of resources, etc. increases, there is a simultaneous increase in interest for systems for efficiently storing and using energy. Further, there is increased interest in new and renewable energy sources that minimize pollution during generation of electricity. An energy storage apparatus may improve energy usage efficiency by interlinking new and renewable energy, a battery that stores energy and a commercial grid. An energy storage apparatus may be used as an uninterruptible power supply to provide emergency operation power or may provide power to industrial equipment in a situation such as interruption of a main power source.

### SUMMARY OF CERTAIN INVENTIVE ASPECTS

One or more embodiments of the present disclosure include a rack housing assembly that intensively houses a plurality of battery trays and electrically connects the housed battery trays so that the housed battery trays are modulated, and an energy storage apparatus having the rack housing assembly.

One or more embodiments of the present disclosure include a rack housing assembly having an improved anti-vibration characteristic with respect to external shocks or vibrations that may be generated during transfer, and an energy storage apparatus having the rack housing assembly.

In one aspect, a rack housing assembly includes, for example, a rack housing defining a plurality of accommodation spaces, each accommodation space having an open front side configured to house a battery tray, and an anchor member formed on at least at one side of the rack housing configured to fix the rack housing to a wall member of an installation space.

In some embodiments, the anchor member is provided at symmetrical positions on at least two sides of the rack housing. In some embodiments, the anchor member includes, for example, a first anchor member positioned and configured to be fixed to a lateral surface of the installation space, and a second anchor member positioned and configured to be fixed to a bottom surface of the installation space. In some embodiments, the first anchor member is positioned at a rear side of the rack housing and the second anchor member is positioned in a lower portion of the rack housing. In some embodiments, the rack housing includes, for example, a cover frame and a stand frame extending parallel to each other and forming upper and lower portions of the rack housing, and a lateral frame extending between the cover frame and the stand frame and across lateral surfaces of the plurality of accommodation spaces. In some embodiments, the first anchor member is fixed to the cover frame or a corner portion between the cover frame and the lateral frame. In some embodiments, the first anchor member includes, for example, a plurality of first anchor members arranged along a long side portion of the cover frame at predetermined intervals. In some embodiments, the second anchor member is fixed to the stand frame. In some embodiments, the second anchor member includes, for example, a plurality of second anchor members arranged along a long side portion of the stand frame at predetermined intervals. In some embodiments, a coupling hole is formed in the anchor member and a fixing member is coupled to the wall member of the installation space by passing through the coupling hole. In some embodiments, the anchor member includes, for example, a flange portion having a flat plate shape that faces the wall member. In some embodiments, the coupling hole is formed in the flange portion. In some embodiments, a plurality of back circuit boards are formed corresponding to the plurality of accommodation spaces and are installed at a rear side of the rack housing. In some embodiments, a power terminal and a communications terminal are provided together at each of the plurality of back circuit boards.

In another aspect, a power storage apparatus includes, for example, a rack housing assembly, including, for example, a rack housing defining a plurality of accommodation spaces, each accommodation spaces having an open front side configured to house a battery tray, and an anchor member formed on at least at one side of the rack housing configured to fix the rack housing to a wall member of an installation space; and a plurality of battery trays, each housed in one of the plurality of accommodation spaces.

In some embodiments, a plurality of back circuit boards are formed corresponding to the plurality of accommodation spaces and are installed at a rear side of the rack housing. In some embodiments, a power terminal and a communications terminal are formed together at each of the plurality of back circuit boards. In some embodiments, the power connection terminal and the communications connection terminal are configured to provide one-to-one electrical connection to the power terminal and the communications terminal are formed at the rear side of each of the plurality of battery trays. In some embodiments, the power terminal and the communications terminal are formed at substantially same position in a forward and backward direction along which each of the plurality of battery trays is inserted, and each of the plurality of battery trays is accommodated in each of the plurality of accommodation spaces at a regular position and configured for simultaneously forming a contact point with the power terminal and the communications terminal. In some embodiments, the anchor member is formed at symmetrical positions on left and right sides of the rack housing. In some embodiments, the anchor member includes, for example, a first anchor member configured to be fixed to a lateral wall of the installation space and a second anchor member configured to be fixed to a bottom surface of the installation space.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus, system or method according to some of the described embodiments can have several aspects, no single one of which necessarily is solely responsible for the desirable attributes of the apparatus, system or method. After considering this discussion, and particularly after reading the section entitled “Detailed Description of Certain Inventive Embodiments” one will understand how illustrated features serve to explain certain principles of the present disclosure.

FIG. 1 is an exploded perspective view of a power storage apparatus according to an embodiment of the present disclosure.

FIG. 2 is a perspective view of a rack housing assembly of FIG. 1.

FIG. 3 illustrates the arrangement and fixed state of a first anchor member of FIG. 2.

FIG. 4 illustrates the arrangement and fixed state of a second anchor member of FIG. 2.

FIG. 5 illustrates the state in which a rack housing of FIG. 1 and a back circuit board are coupled to each other.

FIG. 6 illustrates the structure of power connection and communications connection using the back circuit board of FIG. 5.

### DETAILED DESCRIPTION OF CERTAIN INVENTIVE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements. Since the disclosure may be modified in various ways and have various embodiments, the disclosure will be described in detail with reference to the drawings. However, it should be understood that the disclosure is not limited to a specific embodiment but includes all changes and equivalent arrangements and substitutions included in the spirit and scope of the disclosure. In the following description, if the detailed description of the already known structure and operation may confuse the subject matter of the present invention, the detailed description thereof will be omitted.

Terms “first” and “second” may be used in describing various elements but the elements are not limited to the terms. The terms are used only to distinguish an element from other elements.

Terms used in the following description are to describe specific embodiments and is not intended to limit the disclosure. The expression of singularity includes plurality meaning unless the singularity expression is explicitly different in context. It should be understood that the terms “comprising,” “having,” “including,” and “containing” are to indicate features, numbers, steps, operations, elements, parts, and/or combinations but not to exclude one or more features, numbers, steps, operations, elements, parts, and/or combinations or additional possibilities.

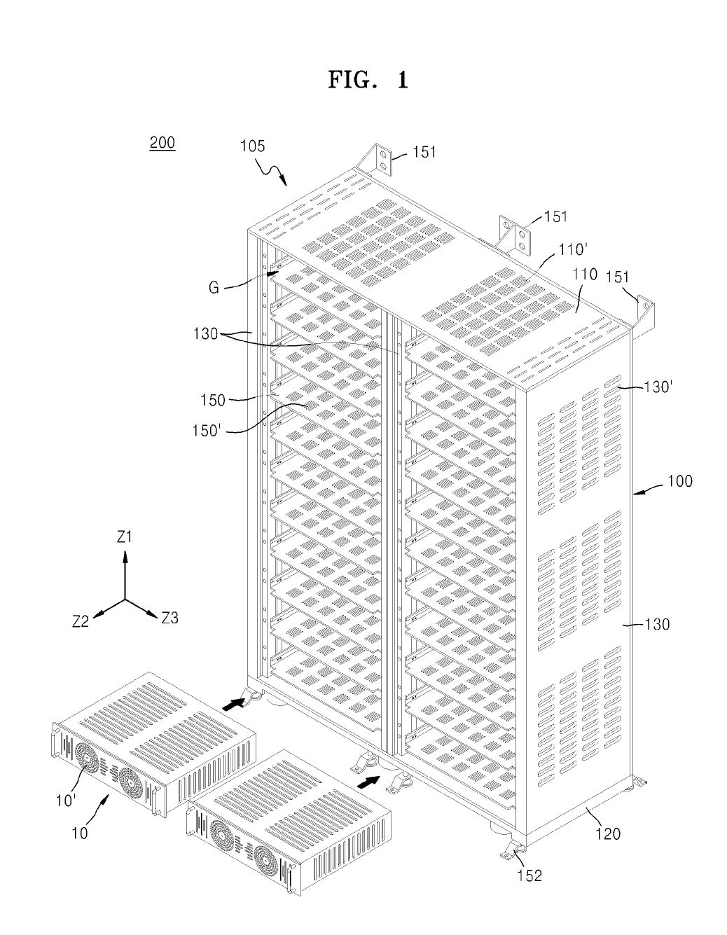

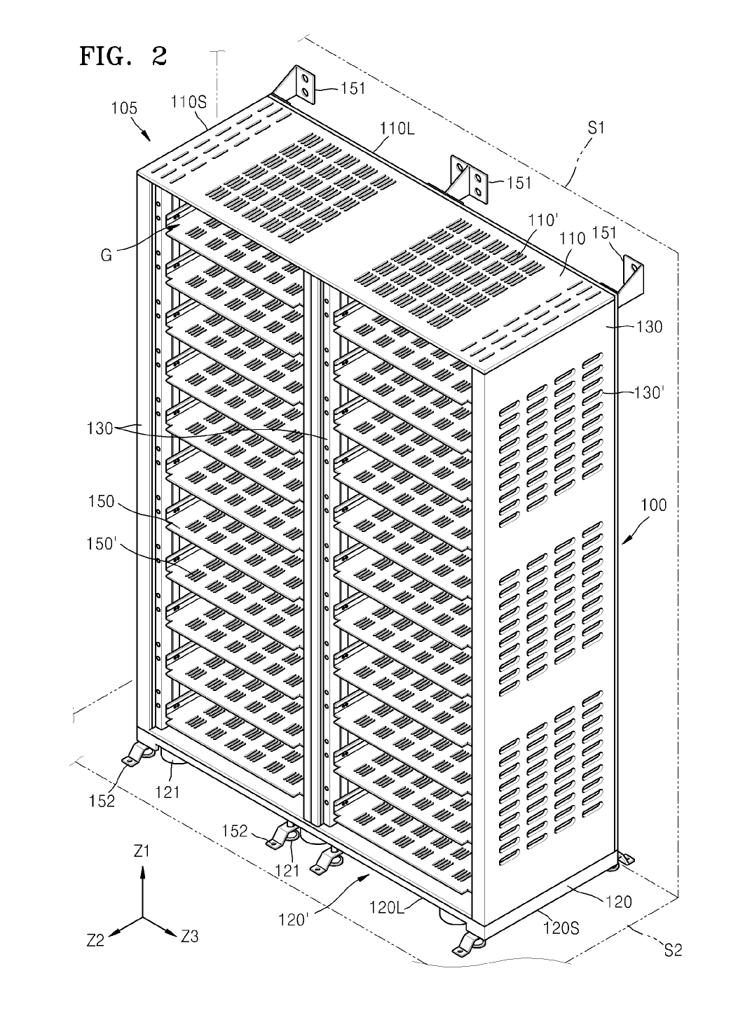

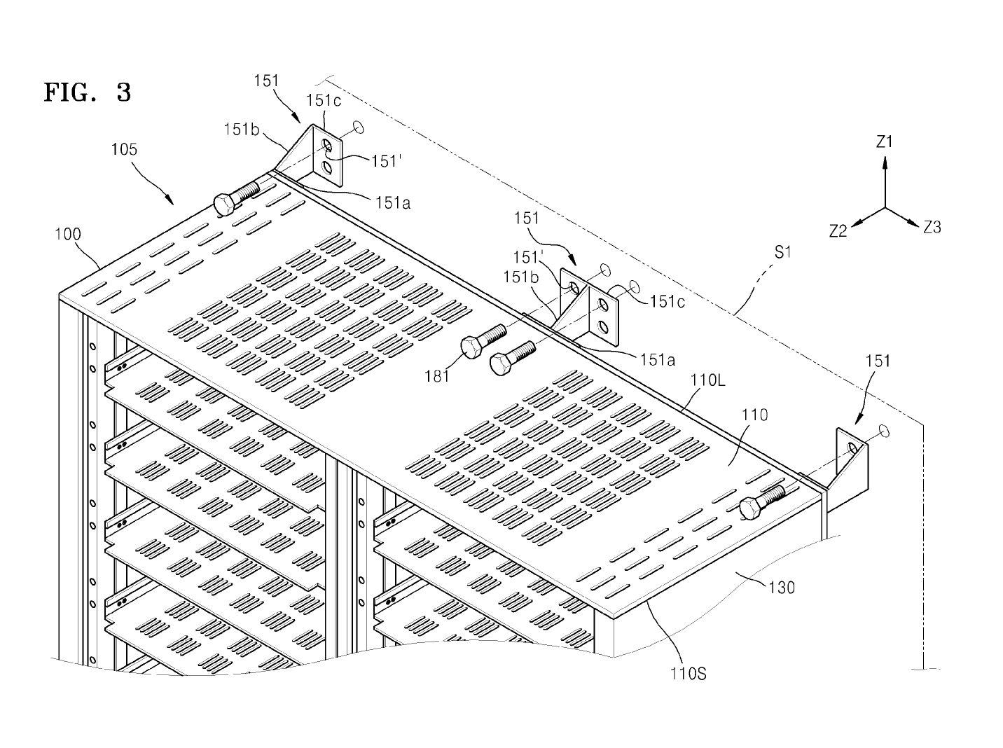

FIG. 1 is an exploded perspective view of a power storage apparatus 200 according to an embodiment of the present disclosure. FIG. 2 is a perspective view of a rack housing assembly 105 of FIG. 1. FIG. 3 is a partially enlarged view of the rack housing assembly 105 of FIG. 2.

Referring to FIGS. 1-3, the power storage apparatus 200 includes a rack housing assembly 105 and a plurality of battery trays 10 housed in the rack housing assembly 105. Each of the battery trays 10 is modularization of a plurality of unit packs (not shown) packed as one unit. The power storage apparatus 200 is formed by connecting the battery trays 10 serially or in parallel. For example, the battery trays 10 each may include a plurality of unit packs having a flat shape and stacked in a vertical direction Z1. A power terminal for outputting a discharge current to an external load (not shown) or inputting a charge current from an external power supply unit (not shown) may be provided in each of the battery trays 10.

The rack housing assembly 105 may include a rack housing 100 for housing the battery trays 10 and first and second anchor members 151 and 152 provided that at least one side of the rack housing 100 to fix the rack housing 100 on wall members including lateral surface S1 and bottom surface S2 of FIG. 2 in a space where the rack housing 100 is placed.

The rack housing 100 is configured to house the battery trays 10 and provide a connector (not shown) for power connection and communications connection between the battery trays 10. The rack housing 100 may provide a plurality of accommodation spaces G for housing the battery trays 10 at a high integrity level. The accommodation spaces G may be provided in multiple numbers in the vertical direction Z1. The neighboring accommodation spaces G arrayed in the vertical direction Z1 may be sectioned by a shelf member 150. The accommodation spaces G may have a column or two or more columns in a horizontal direction Z3. For example, the neighboring accommodation spaces G arrayed in the horizontal direction Z3 may be sectioned by a lateral frame 130. The accommodation spaces G may be designed to house an appropriate number of the battery trays 10 according to the design of power capacity.

The rack housing 100 includes a cover frame 110 and a stand frame 120 respectively forming upper and lower sides of the rack housing 100 and extending in the horizontal direction Z3, and the lateral frame 130 extending in the vertical direction Z1 between the cover frame 110 and the stand frame 120. The rack housing 100 may further include the shelf member 150 that sections inner space of the rack housing 100 into the accommodation spaces G.

For example, the frame members 110, 120, and 130 may form an outer appearance of the rack housing 100 which has a substantially cubic shape. In detail, the cover frame 110 and the stand frame 120 extend in the horizontal direction Z3 from the upper and lower sides of the rack housing 100. The lateral frame 130 extends in the vertical direction Z1 between the cover frame 110 and the stand frame 120 to connect the cover frame 110 and the stand frame 120. The lateral frame 130 may extend in the vertical direction Z1 across the side of the accommodation spaces G where the battery trays 10 are housed, and section a column of the accommodation spaces G according to the vertical direction Z1. The lateral frame 130 is provided between a column of the accommodation spaces G and a neighboring column of the accommodation spaces G in the vertical direction Z1, thereby sectioning the neighboring columns.

For example, the stand frame 120, the cover frame 110, and the lateral frame 130 may be formed as separate members and then coupled to one another, forming a frame of the rack housing 100. In coupling of the stand frame 120, the cover frame 110, and the lateral frame 130, the frame members 110, 120, and 130 may be coupled to one another by a permanent coupling method such as welding, or may be detachably coupled by a mechanical coupling method such as screw coupling.

Alternatively, the frame of the rack housing 100 may be integrally formed. For example, the stand frame 120, the cover frame 110, and the lateral frame 130 may be formed by perpendicularly bending a plate member having a substantially plate shape several times. The frame of the rack housing 100 may be formed by finally coupling both ends of the plate member.

As illustrated in FIG. 2, the cover frame 110 and the stand frame 120 each may have a substantially rectangular shape having a pair of long side portions 110L and 120L and a pair of short side portions 110S and 120S. The cover frame 110 and the stand frame 120 may respectively form the upper and lower sides of the rack housing 100.

The stand frame 120 may perform a function as a stand for a transfer equipment to protect the battery trays 10 housed in the rack housing 100 from external shocks, and facilitate a transfer process. A fork insertion portion 120′ of FIG. 2 in which a fork of a transfer equipment is inserted may be provided at a bottom portion of the stand frame 120. The whole or part of the stand frame 120 may be formed of non-metal based material for anti-vibration design. The stand frame 120 may include a plurality of leg members 121 for supporting the rack housing 100 in an upright posture. The leg members 121 form a part of the stand frame 120. For example, the leg members 121 may has a function to support the rack housing 100 against the bottom surface S2 and may be formed in a variety of shapes if the leg members 121 contact the bottom surface S2.

Although not illustrated in the drawings, a circuit configuration such as a system BMS (Battery Management System) configured for generally controlling the battery trays 10 housed in the rack housing 100 may be provided above the cover frame 110.

As described below, the first and second anchor members 151 and 152 may be provided at the upper and lower portions of the rack housing 100 to provide an anti-vibration characteristic to the rack housing 100. As illustrated in FIG. 2, the first and second anchor members 151 and 152 may be provided at the cover frame 110 and the stand frame 120. In detail, of the first and second anchor members 151 and 152, the first anchor member 151 may be formed at the cover frame 110 or at a position, that is, a corner portion, where the cover frame 110 and the lateral frame 130 meet. The second anchor member 152 may be formed at the stand frame 120. The first and second anchor members 151 and 152, with the rack housing 100, form the rack housing assembly 105.

The shelf member 150 may be arranged at a substantially same interval in the vertical direction Z1 of the rack housing 100 to provide the accommodation spaces G of the battery trays 10 of FIG. 1. The shelf member 150 may be coupled to an inner wall of the rack housing 110, for example, an inner wall of the lateral frame 130 and may be fixed to the inside of the rack housing 100 by a mechanical coupling method such as screw coupling. For example, a flange portion (not shown) is provided at both sides of the shelf member 150 and the shelf member 150 may be fixed to the lateral frame 130 by a coupling member that is coupled to the lateral frame 130 by penetrating the flange portion. The shelf member 150 upholds and supports the battery trays 10 and sections the accommodation spaces G between the battery trays 10 that are arranged in the vertical direction Z1.

As illustrated above, the front side of the accommodation spaces G forms an opening that is open to the outside. The battery trays 10 inserted through the opening may be guided by the shelf member 150 and the frame members 110, 120, and 130 that define the accommodation spaces G and accommodated on the shelf member 150 while sliding on the shelf member 150. The rack housing 100 has the opening formed at the front side thereof to allow insertion of the battery trays 10 and a back circuit board (not shown) provided at the rear side thereof for electric connection with the battery trays 10. Thus, the battery trays 10 inserted from the front side of the rack housing 100 may be slidingly inserted to the back circuit board provided at the rear of the accommodation spacers G. As the battery trays 10 are electrically connected to the back circuit board at the position of that back circuit board, a coupling position of the battery trays 10 may be determined.

Although not illustrated in the drawings, a predetermined restriction unit (not shown), for example, a restriction bar, configured for preventing escape of the battery trays 10 may be provided at the opening formed at the front side of the rack housing 100.

A group of the battery trays 10 may be arrayed, forming a column, in the vertical direction Z1 in the rack housing 100. The battery trays 10 may be arranged in two or more columns, as illustrated in the drawing. The lateral frame 130 may be extendedly formed between one column of the battery trays 10 and a neighboring column of the battery rays 10. The lateral frame 130 sections the accommodation spaces G that neighbor in the horizontal direction Z3.

An air-cooling type heat dissipation structure may be applied to the rack housing 100 for heat dissipation of the battery trays 10. That is, as illustrated in FIG. 1, a vent hole 10′ for introducing low temperature external air into the inside may be formed on the front surface of the battery tray 10. A cooling fan (not shown) may be provided inside or outside the vent hole 10′. The cooling fan (not shown) is a cooling unit configured to forcibly introduce the low temperature external air into the battery trays 10. The low temperature external air forcibly introduced by the cooling fan passes through the inside of the battery trays 10 and is converted into high temperature air through heat transfer, and then may be exhausted to the outside along flow of air.

For example, the cooling fan may be provided on the front surface of the battery trays 10. The air flow by the cooling fan may be introduced into the battery trays 10 through the opening of the rack housing 100 and the vent hole 10′ of the battery trays 10. To facilitate the air flow forcibly moved in the forward and backward direction, the vent hole 10′ may be formed at the front side and the rear side of the battery trays 10. However, the position of the cooling fan is not limited by the example.

Since the opening is formed at the front side of the rack housing 100, the low temperature external air may be smoothly introduced into the inside of the rack housing 100 without flow resistance. The back circuit board configured for electrical connection with the battery trays 10 may be provided at the rear side of the housing 100. Since the back circuit board forms a predetermined opening space (not shown) at the rear side of the rack housing 100, exhaust of air may be smoothly performed. That is, since the back circuit board partially forms the opening space without completely closing the rear side of the rack housing 100, the predetermined opening space may be formed between the back circuit board and the shelf member 150.

A plurality of vent holes 110′ and 130′ for facilitating heat dissipation may be formed at the rack housing 100. For example, as the battery trays 10 contact the low temperature external air through the vent holes 110′ and 130′ or high temperature hot air is exhausted to the outside, the heat dissipation of the battery trays 10 may be facilitated.

For example, a plurality of vent holes 110′ and 130′ may be formed at the lateral frame 130 and the cover frame 110 that are formed at the exterior of the rack housing 100. A group of the vent holes 130′ may be formed at a plurality of positions of the lateral frame 130, forming a group. A group of the vent holes 110′ may be formed at a substantially central position of the cover frame 110. Since the vent holes 110′ and 130′ facilitate thermal contact with a low temperature outside or exhaust high temperature internal heat to the outside, heat dissipation of the battery trays 10 housed in the rack housing 100 may be facilitated. That is, the lateral frame 130 or the cover frame 110 forming the exterior of the rack housing 100 is exposed to the external air. The external air may be directly introduced into the inside of the rack housing 100, or the internal hot air may be directly exhausted to the outside, through the vent holes 110′ and 130′ respectively formed at the cover frame 110 and the lateral frame 130.

Another lateral frame 130 may be arranged between one column of the battery trays 10 and a neighboring column of the battery trays 10 in the vertical direction Z1. The lateral frame 130 is formed inside the rack housing 100 and sections the accommodation spaces G neighboring in the horizontal direction Z3. As hot air generated from the battery trays 10 is transferred to the neighboring battery trays 10, chain thermal runaway or thermal accumulation may be generated from the over heated battery trays 10 . To avoid thermal interference between the battery trays 10, the vent holes 130′ may be omitted in the lateral frame 130 between the battery trays 10.

Also, the main flow of air in the rack housing 100 may be generated in the forward and backward direction Z2 by a cooling fan (not shown) provided at the battery trays 10. To facilitate the flow of air, the vent holes 130′ may be omitted from the lateral frame 130 provided inside the rack housing 100.

In an embodiment shown in FIG. 1, the vent holes 130′ are formed in the lateral frame 130 that forms the exterior of the rack housing 100, whereas the vent holes 130′ are excluded from the lateral frame 130 formed inside the rack housing 100. However, the present disclosure is not limited thereto. That is, by collectively excluding the vent holes 130′ from all the lateral frames 130′, the main air flow in the rack housing 100 is guided in the forward and backward direction Z2 and flow resistance during the air flow in the forward and backward direction Z2 may be reduced.

A plurality of vent holes 150′ may be formed in the shelf member 150 configured to support each of the battery trays 10. The heat accumulated in the rack housing 100 may form a flow that rises according to a lift force. A thermal flow rising through the vent holes 150′ of the shelf member 150 may be generated and exhausted to the outside through the vent holes 110′ of the cover frame 110.

The first and second anchor members 151 and 152 are provided at the rack housing 100. For example, as illustrated in FIG. 2, the first and second anchor members 151 and 152 may be provided at a plurality of positions of the rack housing 100. The first and second anchor members 151 and 152 are configured to maintain the rack housing 100 or the power storage apparatus 200 (which are the same hereinafter) at a regular position, and configured to maintain the rack housing 100 in an upright posture.

In detail, the first and second anchor members 151 and 152 protect the power storage apparatus 200 in response to external vibrations or shocks that may be generated during transfer of the rack housing 100 or in a vibration environment or an earthquake environment. The first and second anchor members 151 and 152 make the rack housing 100 maintained in an upright posture without escaping from a regular position against external vibrations so that an anti-vibration characteristic of the rack housing 100 may be reinforced.

The first and second anchor members 151 and 152 may be configured to prevent the rack housing 100 from being moved or turned over due to external vibrations when the rack housing 100 or the power storage apparatus 200 is exposed to a vibration environment so that the anti-vibration characteristic against the vibration environment may be improved.

The rack housing 100 housing the battery trays 10 forms a heavy body due to its weight, and thus, the battery trays 10 or the rack housing 100 may be highly likely to be damaged during vibrations or overturn. Thus, there is a large demand for protection of an apparatus from unexpected external dynamic environment by improving resistance against external vibrations or shocks.

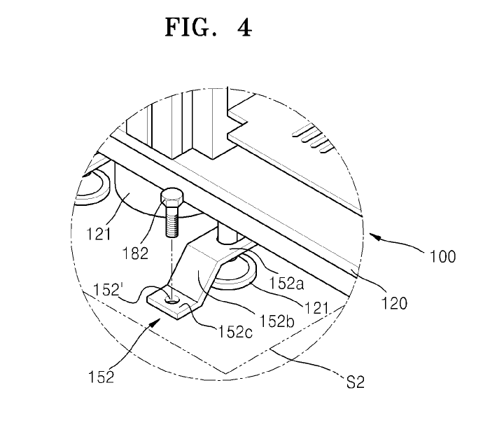

The first and second anchor members 151 and 152 are described in detail with reference to FIGS. 2-4. FIG. 2 illustrates an arrangement state of the first and second anchor members 151 and 152. FIG. 3 illustrates the arrangement and fixed state of the first anchor member 151. FIG. 4 illustrates the arrangement and fixed state of the second anchor member 152.

For example, the first and second anchor members 151 and 152 are fixed to the wall members including the lateral surface S1 and the bottom surface S2 of an installation space for the rack housing 100 through first and second fixing members 181 and 182 (see FIGS. 3 and 4). That is, the first and second anchor members 151 and 152 that are coupled to an external support such as the wall members including the lateral surface S1 and the bottom surface S2 of the installation space where the rack housing 100 is placed may maintain an upright posture without escaping from a regular position in spite of external vibrations or shocks. For example, one end portions of the first and second fixing members 181 and 182 are respectively coupled to the first and second anchor members 151 and 152, whereas the other end portions thereof are respectively coupled to the wall members including the lateral surface S1 and the side surface S2 of the installation space. The wall members of the installation space denote an external structure defining the installation space including the lateral wall S1 and the bottom surface S2 of the installation space where the rack housing 100 or the power storage apparatus 200 is placed.

The first and second anchor members 151 and 152 may be formed on at least one side of the rack housing 100, or at least one or more positions of the rack housing 100. For example, a part of the first anchor member 151 may be coupled to the lateral wall S1 of the installation space through the first fixing member 181, whereas the other part of the second anchor member 152 may be coupled to the bottom surface S2 of the installation space through the second fixing member 182.

The first anchor member 151 is provided at a relatively high level from the bottom surface S2 supporting the rack housing 100. The second anchor member 152 is provided at a relatively low level adjacent to the bottom surface S2. For example, the first anchor member 151 may be coupled to the lateral wall S1 of the installation space where the rack housing 100 is permanently or temporarily placed, whereas the second anchor member 152 may be coupled to the bottom surface S2 of the installation space.

In the arrangement of the rack housing 100, when the rack housing 100 may be arranged such that the rear surface of the rack housing 100 can face the lateral wall Si of the installation space, the first anchor member 151 may be formed at the rear surface of the rack housing 100, that is, in a surface perpendicular to a direction Z2. The rear surface of the rack housing 100 may denote a surface where a back circuit board (not shown) is formed, for example, opposite to the front surface where the accommodation spaces G are open. The second anchor member 152 may be formed at a lower portion of the rack housing 100 and coupled to the bottom surface S2 that supports the rack housing 100.

The installation space of the rack housing 100 may be defined by the wall members including lateral wall S1 and bottom surface S2 surrounding the installation space. The lateral wall S1 is formed extending from the bottom surface S2. The installation space of the rack housing 100 may denote the interior of a container of a transport vehicle or an indoor space where the rack housing 100 is installed. The bottom surface S2 denotes a bottom surface that supports the rack housing 100 or the power storage apparatus 200 including the rack housing 100, for example, the bottom surface S2 of a transport vehicle or the bottom surface S2 of an installation place.

The installation space may denote a space where the rack housing 100 or the power storage apparatus 200 is permanently installed, or a space where the rack housing 100 or the power storage apparatus 200 is temporarily placed in a transport process for moving, for example, an indoor space of a transport vehicle. The first and second anchor members 151 and 152 may be configured to contribute to the anti-vibration characteristic of the rack housing 100 through the coupling to an external support body. For example, the first and second anchor members 151 and 152 may improve the anti-vibration characteristic of the rack housing 100 with respect to earthquake vibrations applied to the installation place of the rack housing 100 or transport vibrations or shocks generated during a transport process of the rack housing 100.

The first anchor member 151 may fix the rack housing 100 at a relatively high level through the coupling to the lateral wall S1 of the installation space. The second anchor member 152 may fix the rack housing 100 at a relatively low level through the coupling to the bottom surface S2 of the installation space. Accordingly, by providing a coupling force at different levels in the vertical direction Z1, the rack housing 100 may be fixed to the regular position and fixed in an upright posture.

For example, the first anchor member 151 may be formed at the cover frame 110 forming the upper portion of the rack housing 100 or at a corner portion formed by the cover frame 110 and the lateral frame 130. The second anchor member 152 may be formed at the stand frame 120 forming the lower portion of the rack housing 100. However, the positions where the first and second anchor members 151 and 152 are not limited thereto and a variety of modifications may exist. The first and second anchor members 151 and 152 may be formed at symmetrical positions on the left and right sides of the rack housing 100, that is, at positions symmetrical in the horizontal direction Z3, to provide a balanced restriction force with respect to the rack housing 100.

Referring to FIG. 3, the first anchor member 151 may be coupled to the lateral wall S1 that faces the first anchor member 151, using the first fixing member 181. For example, the first fixing member 181 is mechanically coupled to the lateral wall S1 facing the first anchor member 151 by passing through a coupling hole 151′ of the first anchor member 151 so that the rack housing 100 may be fixed at the regular position and may maintain an upright posture. For example, the first fixing member 181 may be screw coupled to the lateral wall S1 by passing through the coupling hole 151′ of the first anchor member 151, and a bolt member may be provided as the first fixing member 181. The coupling hole 151′ through which the first fixing member 181 passes is formed in the first anchor member 151. For example, at least two or more coupling holes 151′ may be formed at different position and the first fixing member 181 may be inserted in each coupling hole 151′ by passing through the same.

Alternatively, the first fixing member 181 may have one end coupled to the first anchor member 151 and an extension end extending from the first anchor member 151 toward the lateral wall S1 and coupled to the lateral wall S1. Since the one end and the other end of the first fixing member 181 are respectively fixed to the first anchor member 151 and the lateral wall S1, the rack housing 100 may be fixed at a regular position and be maintained in an upright posture through the first fixing member 181. In detail, the first fixing member 181 may be provided in form of a wire coupled to the coupling hole 151′ of the first anchor member 151. The other end of the first fixing member 181 may be fixed to the lateral wall S1 using an appropriate coupling device (not shown) formed at the lateral wall S1. The first fixing member 181 in form of a wire, providing a balanced tensile force, may firmly fix the rack hosing 100. The first fixing member 181 may be provided in form of, for example, a restriction bar, capable of providing a compressive force with a tensile force.

The first anchor member 151 that is formed at a plurality of positions on the rack housing 100 may prepare for external shocks applied in any directions. The first anchor member 151 may be formed at symmetrical positions and configured to provide a balanced restriction force through the first fixing member 181. The symmetrical positions denote that the first anchor member 151 is formed at symmetrical positions on the left and right sides of the rack housing 100 with respect to the horizontal direction Z3. As illustrated in FIG. 3, the first anchor member 151 may not form a symmetrical arrangement with respect to the forward and backward direction Z2. That is, in consideration of the rear surface of the rack housing 100 being arranged to face the lateral wall S1, the first anchor member 151 may be intensively arranged at the rear surface of the rack housing 100.

For example, in response to a movement to make the rack housing 100 away from the lateral wall S1, the first fixing member 181 may be configured to press the first anchor member 151 against the lateral wall S1 so that the movement of the rack housing 100 may be suppressed. In contrast, in response to a movement to push the rack housing 100 toward the lateral wall S1, the first anchor member 151 formed at the rear surface of the rack housing 100 may be configured to support the rack housing 100 through the facing contact with the lateral wall S1. Since the movement in the forward and backward direction Z2 may be effectively suppressed by the first anchor member 151 selectively formed at the rear surface of the rack housing 100, there is substantially no need to have the front side of the rack housing 100 fixed. However, the present disclosure is not limited thereto. For example, since the front side of the rack housing 100 is coupled to the lateral wall S1 through a fixing member in form of a wire, the coupling state of the rack housing 100 may be further reinforced.

The first anchor member 151 may be formed along the edge of a long side portion 110L of an upper surface of the cover frame 100, that is, a long side portion of the rear surface. Three first anchor members 151 may be arranged along the edge of the long side portion 110L. The first anchor member 151 may protrude upwardly from the cover frame 110. However, the first anchor member 151 may be formed along an edge of a short side portion 110S of the cover frame 110, at a corner where the long side portion 110L and the short side portion 110S meet, or along the long side portion 110L and the short side portion 110S of the cover frame 110. The arrangement of the first anchor member 151 may be modified according to, for example, a positional closeness to the lateral wall S1.

In the embodiment shown in FIG. 3, three anchor members 151 may be formed along the long side portion 110L of the cover frame 110. In detail, a pair of the anchor members 151 may be provided at the left and right end sides of the long side portion 110L. The first anchor member 151 having a wide width providing the coupling hole 151′ may be formed at symmetrical positions on the left and right sides of the substantially center of the long side portion 110L.

For example, the first anchor member 151 may be fixed to the cover frame 110 by a permanent coupling method such as welding or a mechanical coupling method such as screw coupling. The first anchor member 151 may be fixed at a corner portion between the cover frame 110 and the lateral frame 130 by welding or a mechanical coupling method.

The first anchor member 151 includes a connection portion 151b extending toward the lateral wall S1 from a fixed portion 151a fixed to the cover frame 110 or at the corner portion between the cover frame 110 and the later frame 130. The coupling hole 151′ through which the first fixing member 181 passes is provided in a flange portion 151c formed at an end portion of the connection portion 151b to face the lateral wall S1. In detail, the first anchor member 151 may include the fixed portion 151a fixed to the cover frame 110 or at the corner portion between the cover frame 110 and the later frame 130, the flange portion 151c arranged facing the lateral wall S1, where the coupling hole 151′ is formed, and the connection portion 151b connecting the fixed portion 151a and the flange portion 151c.

The flange portion 151c facing the lateral wall S1 may be designed to face and contact the lateral wall S1 if necessary, or to be separated from the lateral wall S1 with an appropriate gap therebetween in some cases. The flange portion 151c may be configured to support the rack housing 100 from the lateral wall S1 through a face facing the lateral wall S1 in response to a movement of the rack housing in the forward and backward direction Z2.

Unlike the embodiment of FIG. 3, the first anchor member 151 may have any shape only if it provides a coupling structure to the first fixing member 181, for example, as a ring shape member (not shown). A first anchor member having a ring shape may be coupled to the lateral wall S1 as a first fixing member in form of a wire is tied to the first anchor member.

Referring to FIG. 4, the second fixing member 182 may be inserted in the second anchor member 152. The second fixing member 182 may be coupled to the bottom surface S2 by passing through the second anchor member 152. For example, a bolt member that is coupled to the bottom surface S2 by passing through a coupling hole 152′ of the second anchor member 152 may be provided as the second fixing member 182. However, the present disclosure is not limited thereof. For example, the second fixing member 182 may be provided in form of a wire having one end portion coupled to the second anchor member 152 and the other end portion coupled to the bottom surface S2.

As the second anchor member 152 is pressed against the bottom surface S2 by the second fixing member 182, the rack housing 100 may be fixed in a state of closely contacting the bottom surface S2. Also, the rack housing 100 may closely fixed to the bottom surface S2 in response to external vibrations or shocks to separate the rack housing 100 from the bottom surface S2. Accordingly, the second anchor member 152 may prevent the rack housing 100 from moving or turning over in response to vibrations.

As illustrated in FIG. 2, the second anchor member 152 may be formed at the symmetrical positions of the rack housing 100, forming a symmetrical arrangement on the left and right sides of the rack housing 100 in the direction Z3 and on the front and rear sides of the rack housing 100 in the direction Z2. Since the rack housing 100 faces the bottom surface S2 throughout the entire area projected downwardly, the second anchor member 152 formed at any positions may be easily fixed to the bottom surface S2.

Accordingly, since the second anchor member 152 is symmetrically formed on the front and rear sides, or on the left and right sides, a coupling state to the bottom surface S2 may be symmetrically formed and provide a symmetrical restriction force in the horizontal direction Z3 and the forward and backward direction Z2. In this case, since the second fixing member 182 presses the second anchor member 152 against the bottom surface S2 at a plurality of positions, the rack housing 100 may be firmly restricted with respect to vibrations in any directions or may resist any vibrations.

The second anchor member 152 may be formed at any position of the rack housing 100, for example, at the stand frame 120 close to the bottom surface S2. The second anchor member 152 may be coupled to the edge of the stand frame 120 to protrude outwardly from the edge of the stand frame 120. The second anchor member 152 may be formed along the long side portion 120L of the stand frame 120 and all eight second anchor members 152, four of them formed on each of the front and rear long side portions 120L may be provided. However, the present disclosure is not limited thereto. The second anchor member 152 may be formed along the short side portion 120S of the stand frame 120 or at a plurality of positions on a plurality of surfaces of the long side portion 120L and the short side portion 120S.

Referring to FIG. 4, the second anchor member 152 may take a substantially flange shape extending outwardly from the stand frame 120 to face the bottom surface S2. For example, the second anchor member 152 may include a fixed portion 152a fixed to the stand frame 120, a flange portion 152c arranged facing the bottom surface S2 and having the coupling hole 152′ formed therein, and a connection portion 152b connecting the fixed portion 152a and the flange portion 152c. The second anchor member 152 may have a shape of a bent plate member or any shape only if it provides a coupling structure to the second fixing member 182.

For example, the second anchor member 152, in detail, the fixed portion 152a of the second anchor member 152, may be fixed to one side of each of the leg members 121 supporting the rack housing 100. The stand frame 120 may include a plurality of the leg members 121 supporting the rack housing 100 against the bottom surface S2. The second anchor member 152 may be coupled to the leg members 121. For example, the second anchor member 152 may be fixed to the leg members 121 in a permanent coupling method such as welding or a mechanical coupling method. The leg members 121 may be formed at a plurality of positions to stably support the rack housing 100 against the bottom surface S2. However, the present disclosure is not limited thereto and the leg members 121 may be formed in a variety of shapes only if they provide a contact surface to the bottom surface S2.

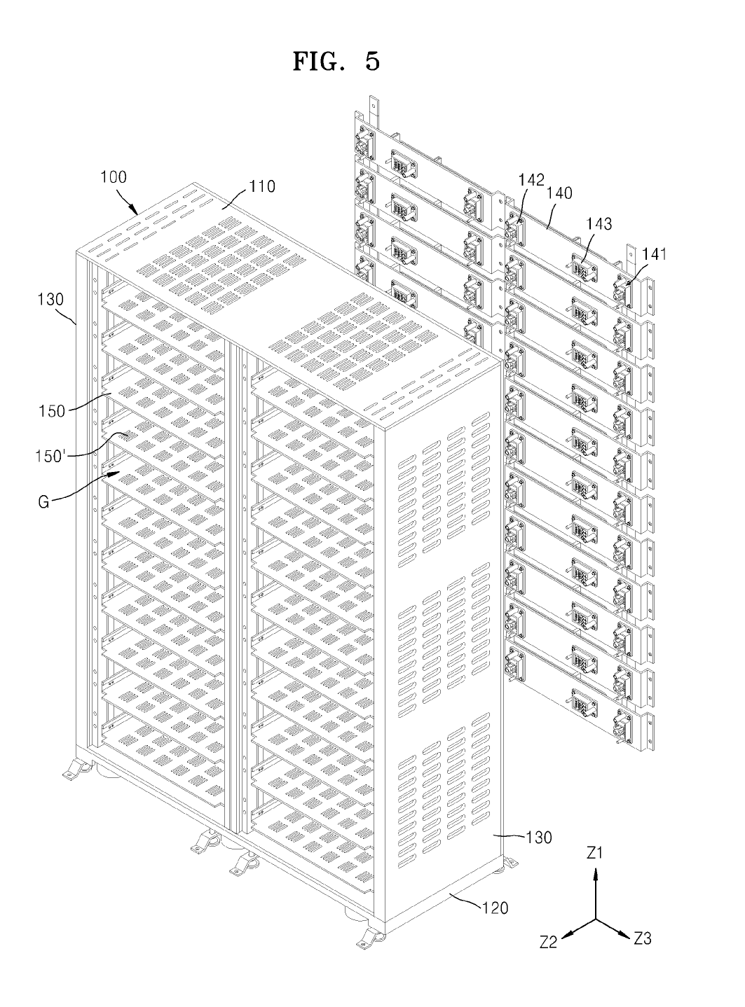

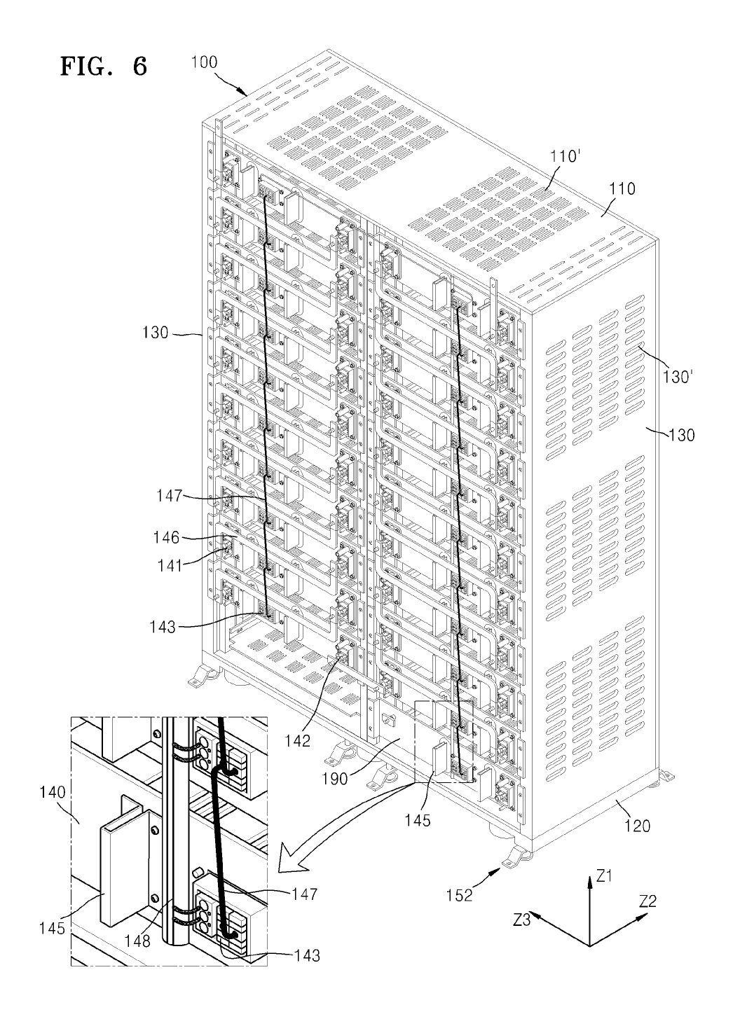

FIG. 5 illustrates the state in which the rack housing 100 of FIG. 1 and a back circuit board 140 are coupled to each other. FIG. 6 illustrates the rear side of the rack housing 100 of FIG. 5. FIGS. 5 and 6 illustrate the installation structure of the back circuit board 140 and power connection and communications connection using the back circuit board 140. In FIGS. 5 and 6, the first anchor member 151 is omitted for convenience of understanding.

Referring to FIGS. 5 and 6, a plurality of back circuit boards 140 are installed at the rear side of the rack housing 100. In detail, each of the back circuit boards 140 is installed at the rear side of each of the accommodation spaces G to correspond to the accommodation spaces G of the rack housing 100 and coupled to the rack housing 100 from the back side of the rack housing 100. For example, the back circuit boards 140 may be screw coupled to the lateral frame 130 of the rack housing 100. Each of the back circuit boards 140 may be individually formed to make one-to-one match corresponding to the battery trays 10 housed in the accommodation spaces G.

Each of the back circuit boards 140 includes first and second power terminals 141 and 142 and a communications terminal 143 for forming electric connection to a power connection terminal (not shown) and configured for forming communications connection terminal (not shown) of each of the battery trays 10, respectively. The first and second power terminals 141 and 142 and the communications terminal 143 may form one-to-one electric connection to the power connection terminal and the communications connection terminal of each of the battery trays 10.

The first and second power terminals 141 and 142 and the communications terminal 143 may modularize the battery trays 10 by electrically connecting them in serial or in parallel through the line connection therebetween, and electrically connect between the battery trays 10, or between the battery trays 10 and a higher BMS (rack BMS) for generally controlling the battery trays 10, to be capable of communicating therebetween.

For example, since the first and second power terminals 141 and 142 and the communications terminal 143 are integrally formed on one of the back circuit boards 140, power connection and communications connection may be simultaneously achieved through the connection to the battery trays 10 that is a connection counterparty of the back circuit boards 140. A connection job may be made easier by using a batch connection structure of the first and second power terminals 141 and 142 and the communications terminal 143.

As it is illustrated in FIG. 5, the back circuit boards 140 are installed at the rear side of the rack housing 100. In detail, the back circuit boards 140 are respectively coupled to the rear side of each of the accommodation spaces G. In this state, when the battery trays 10 are respectively installed through the accommodation spaces G, each of the battery trays 10 is pushed from the front side toward the rear side of each of the accommodation spaces G so that the battery trays 10 may be smoothly connected to the back circuit boards 140 of the rack housing 100. For example, a circuit board (not shown) for forming an electric contact point with each of the back circuit boards 140 of the rack housing 100 may be formed at the rear side of each of the battery trays 10.

Each of the battery trays 10 that is inserted from the front side of the rack housing 100 may be slidingly inserted to a position of each of the back circuit boards 140 provided at the rear side of each of the accommodation spaces G. As the battery trays 10 respectively make electrical coupling with the back circuit boards 140, a coupling position may be determined.

Referring to FIG. 6, the back circuit boards 140 installed at the rear side of the rack housing 100 are connected to each other via a bus member 146. For example, the first power terminal 141 and the second power terminal 142, each having an opposite polarity, may be formed at one side end and the other side end of each of the back circuit boards 140. The first power terminal 141 of each of the back circuit boards 140 is electrically connected to the second power terminal 142 of neighboring one of the back circuit boards 140 via the bus member 146. Similarly, the second power terminal 142 of each of the back circuit boards 140 is electrically connected to the first power terminal 141 of neighboring one of the back circuit boards 140 via the bus member 146. As such, since the first and second power terminals 141 and 142 of the neighboring back circuit boards 140, having the opposite polarities, are connected via the bus member 146, the battery trays 10 housed in the rack housing 100 may configure a serial connection. The first and second power terminals 141 and 142 arranged at both ends of a power path formed by connecting the neighboring battery trays 10 in a chain connection, that is, the first and second power terminals 141 and 142 that are not connected to the neighboring battery trays 10 in FIG. 6, may form connection terminals for connection with an external circuit (not shown).

However, the present disclosure is not limited thereto and, for example, the battery trays 10 housed in the rack housing 100 may be electrically connected to each other in parallel. Considering the output voltage and output capacity of the power storage apparatus 200, the battery trays 10 may have a mixed connection structure of serial and parallel connections. The bus member 146 may be embodied by a power cable having a sufficient thickness considering resistance loss of a connection path.

A communications terminal 143 may be provided substantially at the center position of each of the back circuit boards 140. The communications terminal 143 may be connected to the communications terminal 143 of neighboring one of the battery trays 10 via a communications cable 147. Each communications terminal 143 is connected to the neighboring communications terminal 143 via the communications cable 147. The communications terminal 143 located at an end may be connected to, for example, a rack BMS circuit board 190 installed at the lower portion of the rack housing 100, and information collected through each communications terminal 143 may be transferred to a rack BMS (not shown). That is, the one of the battery trays 10 arranged at an end of the communications cable 147 may transfer status information of itself and that of another battery tray to the rack BMS.

A direct voltage supply cable 148 extending across the back circuit boards 140 is connected to a voltage supply terminal formed at the communications terminal 143 and may provided, for example, a regular voltage such as 24 V.

A spacer 145 may be formed at each of the back circuit boards 140 of the rack housing 100. The spacer 145 is provided to secure a wiring space occupied by wirings installed at the rear side of the rack housing 100, that is, the bus member 146 and the communications cable 147. For example, the spacer 145 secures a predetermined wiring space between the lateral wall S1 and the rack housing 100 to prevent any possible intrusion into the wiring space when the rear side of the rack housing 100 closely contacts the lateral wall S1 of the installation space. The spacer 145 may be provided in a variety of shapes. As illustrated in FIG. 6, the spacer 145 may be integrally formed with the back circuit boards 140 and protrude backwardly from the back circuit boards 140 to a predetermined length.

The rack BMS for generally controlling the battery trays 10 housed in the rack housing 100 and charge/discharge operations of the battery trays 10 may be arranged in a part of the accommodation spaces G, for example, the accommodation spaces G provided in the lower portion of the rack housing 100.

As described above, according to the present disclosure, the rack housing assembly and the power storage apparatus including the rack housing assembly intensively accommodate a plurality of battery trays to structurally modularize the battery trays and electrically modularized by providing the power connection and communications connection structures to the housed battery trays.

Also, since the anchor structure for restricting a rack structure at a regular position and maintaining the rack structure in an upright posture in the installation space where the rack structure is accommodated, is provided, an anti-vibration characteristic may be improved.

While the present invention has been described in connection with certain exemplary embodiments, it will be appreciated by those skilled in the art that various modifications and changes may be made without departing from the scope of the present disclosure. It should be understood that the exemplary embodiments described therein should be considered in a descriptive sense only and not for purposes of limitation. Descriptions of features or aspects within each embodiment should typically be considered as available for other similar features or aspects in other embodiments. Indeed, it will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Thus, while the present disclosure has described certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A rack housing assembly, comprising:
a rack housing defining a plurality of accommodation spaces, each accommodation space having an open front side configured to house a battery tray; and
an anchor member formed on at least at one side of the rack housing configured to fix the rack housing to a wall member of an installation space.

2. The rack housing assembly of claim 1, wherein the anchor member is provided at symmetrical positions on at least two sides of the rack housing.

3. The rack housing assembly of claim 1, wherein the anchor member comprises a first anchor member positioned and configured to be fixed to a lateral surface of the installation space, and a second anchor member positioned and configured to be fixed to a bottom surface of the installation space.

4. The rack housing assembly of claim 3, wherein the first anchor member is positioned at a rear side of the rack housing and the second anchor member is positioned in a lower portion of the rack housing.

5. The rack housing assembly of claim 4, wherein the rack housing comprises:
a cover frame and a stand frame extending parallel to each other and forming upper and lower portions of the rack housing; and
a lateral frame extending between the cover frame and the stand frame and across lateral surfaces of the plurality of accommodation spaces.

6. The rack housing assembly of claim 5, wherein the first anchor member is fixed to the cover frame or a corner portion between the cover frame and the lateral frame.

7. The rack housing assembly of claim 5, wherein the first anchor member comprises a plurality of first anchor members arranged along a long side portion of the cover frame at predetermined intervals.

8. The rack housing assembly of claim 5, wherein the second anchor member is fixed to the stand frame.

9. The rack housing assembly of claim 8, wherein the second anchor member comprises a plurality of second anchor members arranged along a long side portion of the stand frame at predetermined intervals.

10. The rack housing assembly of claim 1, wherein a coupling hole is formed in the anchor member and a fixing member is coupled to the wall member of the installation space by passing through the coupling hole.

11. The rack housing assembly of claim 10, wherein the anchor member comprises a flange portion having a flat plate shape that faces the wall member and, wherein the coupling hole is formed in the flange portion.

12. The rack housing assembly of claim 1, wherein a plurality of back circuit boards are formed corresponding to the plurality of accommodation spaces and are installed at a rear side of the rack housing.

13. The rack housing assembly of claim 12, wherein a power terminal and a communications terminal are provided together at each of the plurality of back circuit boards.

14. A power storage apparatus, comprising:
the rack housing assembly of claim 1; and
a plurality of battery trays, each housed in one of the plurality of accommodation spaces.

15. The power storage apparatus of claim 14, wherein a plurality of back circuit boards are formed corresponding to the plurality of accommodation spaces and are installed at a rear side of the rack housing.

16. The power storage apparatus of claim 15, wherein a power terminal and a communications terminal are formed together at each of the plurality of back circuit boards.

17. The power storage apparatus of claim 16, wherein the power connection terminal and the communications connection terminal are configured to provide one-to-one electrical connection to the power terminal and the communications terminal are formed at the rear side of each of the plurality of battery trays.

18. The power storage apparatus of claim 17, wherein the power terminal and the communications terminal are formed at substantially same position in a forward and backward direction along which each of the plurality of battery trays is inserted, and each of the plurality of battery trays is accommodated in each of the plurality of accommodation spaces at a regular position and configured for simultaneously forming a contact point with the power terminal and the communications terminal.

19. The power storage apparatus of claim 14, wherein the anchor member is formed at symmetrical positions on left and right sides of the rack housing.

20. The power storage apparatus of claim 14, wherein the anchor member comprises a first anchor member configured to be fixed to a lateral wall of the installation space and a second anchor member configured to be fixed to a bottom surface of the installation space.
